(19) United States
(12) Patent Application Publication
(10) Pub. No.: US 2025/0056788 A1
(43) Pub. Date: Feb. 13, 2025

(54) SEMICONDUCTOR DEVICE AND METHOD FOR FABRICATING THE SAME

(71) Applicant: SK hynix Inc., Gyeonggi-do (KR)

(72) Inventors: Hye Won YOON, Gyeonggi-do (KR); Seung Hwan KIM, Gyeonggi-do (KR)

(21) Appl. No.: 18/405,364

(22) Filed: Jan. 5, 2024

(30) Foreign Application Priority Data
Aug. 11, 2023 (KR) 10-2023-0105588

(51) Int. Cl. H10B 12/00

(52) U.S. Cl. CPC H10B 12/30; H10B 12/03; H10B 12/05

(57) ABSTRACT

A semiconductor device includes a lower structure; a plurality of horizontal conductive layers oriented in a direction parallel to a surface of the lower structure; a plurality of reservoir capacitors commonly coupled to first-side ends of the horizontal conductive layers, wherein each of the plurality of the reservoir capacitors is vertically stacked over the lower structure, and includes a cylindrical storage node; and a vertical conductive line commonly coupled to second-side ends opposite to first-side ends of the horizontal conductive layers, extending in a direction perpendicular or substantially perpendicular to the surface of the lower structure, and including a plurality of electrode portions, each electrode portion being symmetrical with the cylindrical storage node of a corresponding reservoir capacitor.

### CROSS-REFERENCE TO RELATED APPLICATIONS

The present application claims priority under 35 U.S.C 119 (a) to Korean Patent Application No. 10-2023-0105588, filed on Aug. 11, 2023, which is incorporated herein by reference in its entirety.

### BACKGROUND

### 1. Field

Various embodiments of the present invention relate generally to a semiconductor device, and more particularly, to a semiconductor device having a three-dimensional structure, and a method for fabricating the semiconductor device.

### 2. Description of the Related Art

The size of a memory cell is being reduced continuously to increase the net die of a memory device. As the size of memory cells is miniaturized, it is required to reduce parasitic capacitance Cb and increase the capacitance as well. However, it is difficult to increase the net die due to the structural limitation of the memory cells. Recently, three-dimensional semiconductor memory devices which stack memory cells in a three-dimensional array have been proposed. Extensive research efforts are currently employed for developing three-dimensional semiconductor devices which are smaller, higher capacity, and exhibit improved performance characteristics.

### SUMMARY

Embodiments of the present invention are directed to a highly integrated three dimensional semiconductor device (simply referred to hereinafter as a semiconductor device), and a method for fabricating the same.

In accordance with an embodiment of the present invention, a semiconductor device includes: a lower structure; a plurality of horizontal conductive layers oriented in a direction parallel to a surface of the lower structure; a plurality of reservoir capacitors commonly coupled to first-side ends of the horizontal conductive layers, wherein each of the plurality of the reservoir capacitors is vertically stacked over the lower structure, and includes a cylindrical storage node; and a vertical conductive line commonly coupled to second-side ends opposite to first-side ends of the, extending in a direction perpendicular or substantially perpendicular to the surface of the lower structure, and including a plurality of electrode portions, each electrode portion being symmetrical with the cylindrical storage node of a corresponding reservoir capacitor.

In accordance with another embodiment of the present invention, a method for fabricating a semiconductor device includes: forming a plurality of horizontal conductive layers that are oriented in a direction parallel to a surface of a lower structure; forming a plurality of cylindrical storage nodes and a plurality of electrode portions that are coupled to both ends of the horizontal conductive layers and bilaterally symmetrical; forming a dielectric layer and a sacrificial layer suitable for covering the cylindrical storage nodes and the electrode portions; exposing the electrode portions by removing the sacrificial layer; and forming a reservoir capacitor stacked over the lower structure and extending in a direction perpendicular or substantially perpendicular to the surface of the lower structure by forming a plate node and a conductive layer over the dielectric layer and the electrode portions, respectively.

In accordance with another embodiment of the present invention, a semiconductor device includes: a lower structure; a first array including first vertically stacked capacitors disposed over the lower structure; and a second array that is horizontally spaced apart from the first array and includes second vertically stacked capacitors and a sharing portion commonly connected to the second vertically stacked capacitors; the sharing portion of the second array, horizontal portion connected to each of the second vertically stacked capacitors; a cylinder portion including an inner surface, an upper outer surface, a lower outer surface connected to the horizontal portion, and a vertical outer surface between the upper outer surface and the lower outer surface; an inner portion disposed on the inner surface of the cylinder portion; an outer portion disposed on the upper outer surface and lower outer portion of cylinder portion.

In accordance with another embodiment of the present invention, a semiconductor device includes: a first peripheral circuit including a plurality of control circuits; a memory cell array including vertically stacked memory cells disposed on the first peripheral circuit; and a second peripheral circuit that is horizontally spaced apart from the memory cell array and includes second vertically stacked capacitors and a sharing portion commonly connected to the vertically stacked capacitors; the sharing portion of the second peripheral circuit, horizontal portion connected to each of the vertically stacked capacitors; a cylinder portion including an inner surface, an upper outer surface, a lower outer surface connected to the horizontal portion, and a vertical outer surface between the upper outer surface and the lower outer surface; an inner portion disposed on the inner surface of the cylinder portion; an outer portion disposed on the upper outer surface and lower outer portion of cylinder portion.

These and other features and advantages of the present invention will become better understood by the skilled person from the following detailed description and drawings.

### BRIEF DESCRIPTION OF THE DRAWINGS

FIG. 1 is a schematic block diagram illustrating a semiconductor device in accordance with an embodiment of the present invention.

FIG. 2 is a cross-sectional view taken along a line B-B′ shown in FIG. 1.

FIGS. 3 and 4 illustrate semiconductor devices in accordance with other embodiments of the present invention.

FIGS. 5A to 5P are cross-sectional views illustrating a method for fabricating a semiconductor device in accordance with an embodiment of the present invention.

FIGS. 6A to 6Q are cross-sectional views illustrating a method for fabricating a semiconductor device in accordance with another embodiment of the present invention.

### DETAILED DESCRIPTION

Various embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout this disclosure, like reference numerals refer to like parts throughout the various figures and embodiments of the present invention.

The drawings are not necessarily to scale and in some instances, proportions may have been exaggerated to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

The following embodiments of the present invention relate to a semiconductor device including vertically stacked memory cells characterized with increased memory cell density and reduced parasitic capacitance.

In some embodiments, the semiconductor device may be implemented as a Dynamic Random Access Memory (DRAM) including capacitors for stable power supply or stabilization of transmitted signals as well as memory cell arrays. In particular, in order to stabilize the voltage from factors such as noise, a reservoir capacitor with a large capacitance may be formed in the spare space of a peripheral circuit.

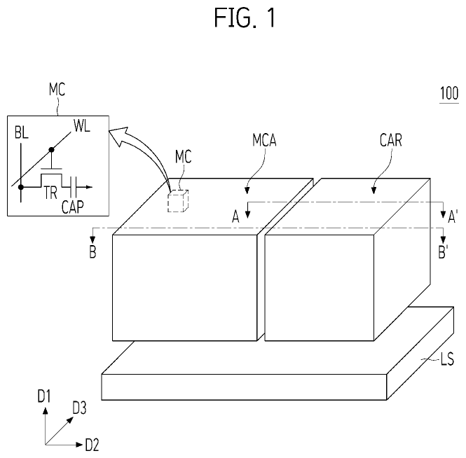

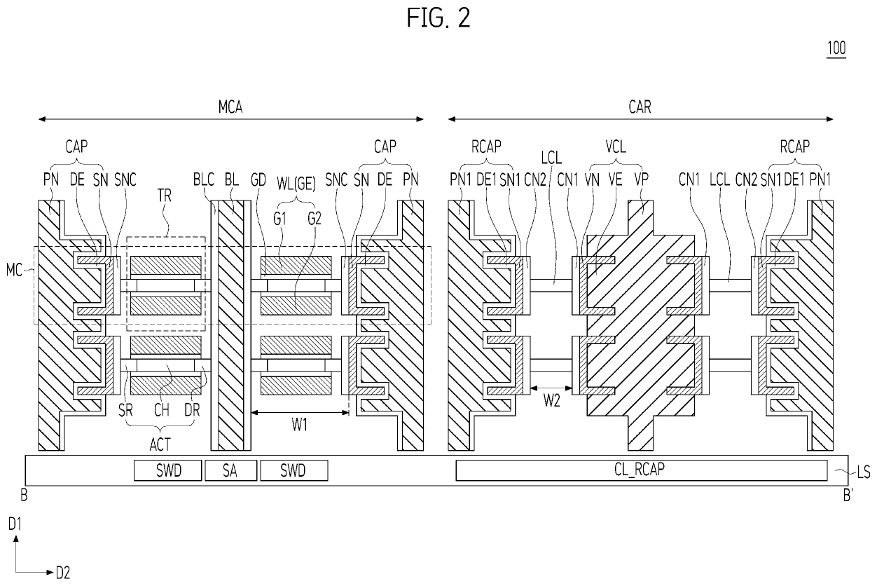

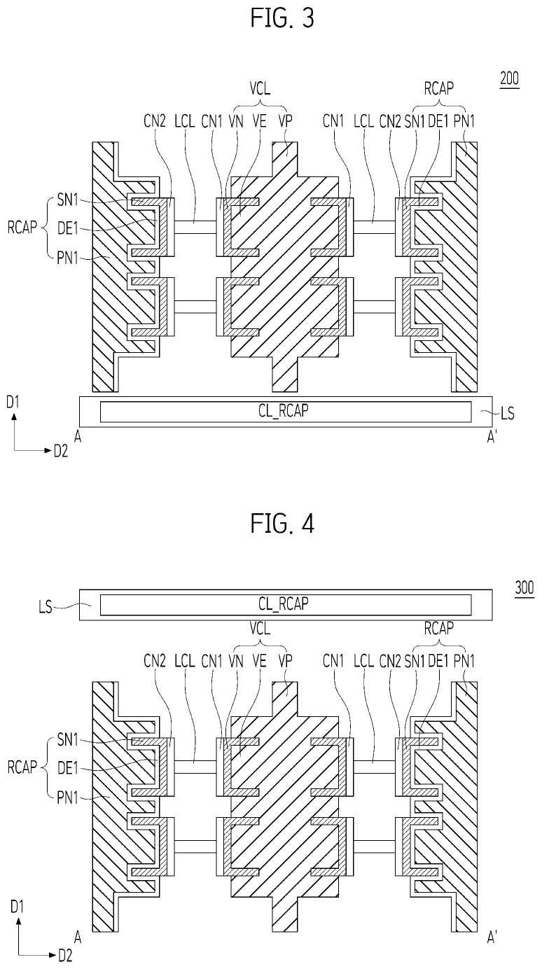

FIG. 1 is a schematic block diagram illustrating a semiconductor device in accordance with an embodiment of the present invention. FIG. 2 is a cross-sectional view taken along a line B-B′ shown in FIG. 1. FIGS. 3 and 4 illustrate semiconductor devices in accordance with other embodiments of the present invention.

Referring to FIGS. 1 and 2, a semiconductor device 100 according to an embodiment of the present invention may include a lower structure LS, a memory cell array MCA, and a reservoir capacitor array CAR. The memory cell array MCA and the reservoir capacitor array CAR may be disposed over the lower structure LS. Each of the memory cell array MCA and the reservoir capacitor array CAR may be disposed in a first direction D1 over the lower structure LS. The first direction D1 may be a vertical direction perpendicular to the top surface of the lower structure LS. The memory cell array MCA and the reservoir capacitor array CAR may be disposed adjacent to each other in a second direction D2. The second direction D2 may be a first horizontal direction. The second direction D2 may be a horizontal direction parallel to the top surface of the lower structure LS. A third direction may be a second horizontal direction. The third direction may be a horizontal direction parallel to the top surface of the lower structure LS. The second direction D2 and the third direction D3 may be orthogonal. The first, second, and third directions D1, D2, and D3 may be orthogonal to each other.

The memory cell array MCA may include a plurality of memory cells MC that are arranged three-dimensionally. Each memory cell MC may include a switching element TR and a data storage element CAP operatively coupled to each other. The data storage element CAP may be coupled to a bit line BL through the switching element TR. The switching element TR may be a transistor (e.g., Field Effect Transistor, FET), and the data storage element CAP may be a capacitor. Hereinafter, the switching element TR may be simply referred to as a transistor, and the data storage element CAP may be simply referred to as a cell capacitor. The transistor TR and the capacitor CAP may be disposed between a word line WL and a bit line BL, which are arranged to cross each other. The bit line BL may be referred to as “a first conductive line”, and the word line WL may be referred to as “a second conductive line”.

The transistor TR of the individual memory cell MC may include a horizontal active layer ACT, and the horizontal active layer ACT may be coupled to a cell capacitor CAP and a bit line BL. The horizontal active layer ACT may be referred to as “a horizontal layer ACT”. The horizontal active layer ACT may include a first source/drain region DR, a second source/drain region SR, and a channel CH horizontally disposed between the first source/drain region DR and the second source/drain region SR. The transistor TR may further include a word line WL or a gate electrode GE that overlaps with the channel CH. The gate electrode GE may be part of the word line WL, the first source/drain region DR may be coupled to the bit line BL, and the second source/drain region SR may be coupled to the cell capacitor CAP. In this way, one side of the horizontal active layer ACT may be coupled to the bit line BL, and another side of the horizontal active layer ACT may be coupled to the cell capacitor CAP. The horizontal active layer ACT may also be referred to as a horizontal active layer or a thin-body active layer.

An individual memory cell MC may include a single transistor TR and a single cell capacitor CAP. This may be referred to as a ‘1T1C cell’. A single cell capacitor CAP of the 1T1C cell may store data, and a single transistor TR may serve as an access device that reads data from the single cell capacitor CAP or writes data into the single cell capacitor CAP. According to another embodiment of the present invention, the single transistor TR may serve as a selective device.

The memory cell array MCA may include a plurality of bit lines BL, a plurality of transistors TR, and a plurality of cell capacitors CAP. The cell capacitors CAP may be stacked in the first direction D1.

The memory cell array MCA may include a plurality of memory cells MC that are stacked in the first direction D1. The memory cells MC may be arranged in the second direction D2 and a third direction D3. The memory cell array MCA may include a three-dimensional array of memory cells MC. The memory cell array MCA may also include a three-dimensional array of cell capacitors CAP. The memory cell array may be referred to as “a first array”.

The reservoir capacitor array CAR may include a plurality of reservoir capacitors RCAP that are stacked in the first direction D1 and are also arranged along the second direction and third directions D2 and D3. The reservoir capacitor array may be referred to as “a second array”. The reservoir capacitor array CAR may include at least one three-dimensional array of reservoir capacitors RCAP.

The reservoir capacitors RCAP may have the same or substantially the same structure as that of the cell capacitors CAP. The reservoir capacitors RCAP may be formed at the same levels as the cell capacitors CAP. The reservoir capacitors RCAP may be formed to have the same size as the cell capacitors CAP. The reservoir capacitors RCAP and the cell capacitors CAP may have the same or substantially the same capacitance.

The memory cell array MCA may be a first column array including cell capacitors CAP that are stacked in the first direction D1. The cell capacitors CAP of the first column array may be referred to as a cell capacitor array. The reservoir capacitor array RCAP may be a second column array including reservoir capacitors RCAP that are stacked in the first direction D1. In the first and second column arrays, each of the cell capacitors CAP and the reservoir capacitors RCAP may include storage nodes SN and SN1 that are separated from each other. Each of the cell capacitors CAP and the reservoir capacitors RCAP may include plate nodes PN and PN1 that are coupled to each other.

The individual transistors TR may include the horizontal active layer ACT and the word line WL. Each word line WL may include first and second word lines G1 and G2 that are facing each other with the horizontal active layer ACT interposed therebetween. A gate dielectric layer GD may be disposed between the horizontal active layer ACT and the word line WL. The gate dielectric layer GD may be formed between the first word line G1 and the horizontal active layer ACT and also between the second word line G2 and the horizontal active layer ACT. The cell capacitors CAP and the reservoir capacitors RCAP may include storage nodes SN and SN1, dielectric layers DE and DE1, and plate nodes PN and PN1, respectively.

The bit line BL of the memory cell array MCAR may have a pillar shape extending in the first direction D1. A cross-sectional shape of the pillar may differ and may, for example, be rectangular, circular, or oval. The lateral active layer ACT may have a bar shape with its long axis extending along the second direction D2. The word line WL may have a line shape extending in the third direction D3. The bit line BL may be vertically oriented in the first direction D1. The bit line BL may be referred to as a vertically oriented bit line or a pillar-type bit line.

The bit line BL may be made of a conductive material including, for example, a silicon-based material, a metal-based material, or a combination thereof. The bit line BL may be made of or include silicon, a metal, a metal nitride, a metal silicide, or a combination thereof. In some embodiments, the bit line BL may be made or include polysilicon, titanium nitride, tungsten, or a combination thereof. For example, the bit line BL may be made or include polysilicon or titanium nitride (TIN) that is doped with an N-type impurity. The bit line BL may be made of or include a TiN/W stack including a layer of titanium nitride and a layer of tungsten formed over the layer of the titanium nitride.

A bit line contact node BLC may surround the outer side wall of the bit line BL. The bit line contact node BLC may be coupled to the first source/drain regions DR of the active layers ACT. The bit line contact node BLC may be made of or include a conductive material, such as, for example, a silicon-based material, a metal-based material, or a combination thereof. In some embodiments, the bit line contact node BLC may be made of or include silicon, a metal, a metal nitride, a metal silicide, or a combination thereof. The bit line contact node BLC may be made of or include polysilicon, titanium nitride, tungsten, or a combination thereof. For example, the bit line contact node BLC may be made of or include polysilicon (N-type doped polysilicon) or titanium nitride (TiN) that is doped with an N-type impurity. The bit line BL may be made of or include a TiN/W stack including titanium nitride or tungsten over titanium nitride, and the bit line contact node BLC may be made of or include N-type doped polysilicon.

The word lines WL may extend in the third direction D3, and the horizontal active layer ACT may extend in the second direction D2. The horizontal active layer ACT may be arranged horizontally in the second direction D2 from the bit line BL. The word lines WL may each include a pair of word lines, that is, a first word line G1 and a second word line G2. The first word line G1 and the second word line G2 in each pair may face each other in the first direction D1 with the horizontal active layer ACT interposed therebetween. The gate dielectric layer GD may be formed on the upper and lower surfaces of the horizontal active layer ACT.

In the word line WL, the first word line G1 and the second word line G2 may have the same potential. For example, the first word line G1 and the second word line G2 may form a pair, and the same word line driving voltage may be applied to the first word line G1 and the second word line G2. As described above, the semiconductor device 100 according to this embodiment of the present invention may have a double word line structure in which two first and second word lines G1 and G2 are disposed adjacent to one horizontal active layer ACT. The double word line structure may also be referred to as a double gate structure.

The horizontal active layer ACT may be made of or include a semiconductor material. The horizontal active layer ACT may be made of or include a silicon-containing layer or a silicon germanium-containing layer. For example, the horizontal active layer ACT may made of or include silicon, monocrystalline silicon, doped polysilicon, undoped polysilicon, amorphous silicon, silicon germanium, or a combination thereof. According to another embodiment of the present invention, the horizontal active layer ACT may be made of or include nano-wires or nano-sheets. The nano-wires and nano-sheets may be formed of or include a semiconductor material. According to another embodiment of the present invention, the horizontal active layer ACT may be made of or include an oxide semiconductor material. The first source/drain region DR and the second source/drain region SR may be formed in the horizontal active layer ACT by an ion implantation process or a plasma doping process of impurities.

The horizontal active layer ACT may have a smaller thickness than the thickness of the first and second word lines G1 and G2. The vertical thickness of the horizontal active layer ACT in the first direction D1 may be thinner than the vertical thickness of each of the first and second word lines G1 and G2 in the first direction D1. Herein, the thin horizontal active layer ACT may be referred to as a thin-body horizontal active layer.

The gate dielectric layer GD may be made of or include silicon oxide, silicon nitride, a metal oxide, a metal oxynitride, a metal silicate, a high-k material, a ferroelectric material, an anti-ferroelectric material, or a combination thereof. For example, the gate dielectric layer GD may be made of or include SiO₂, Si₃N₄, HfO₂, Al₂O₃, ZrO₂, AlON, HfON, HfSiO, HfSiON, HfZrO or a combination thereof.

The first and second word lines G1 and G2 of the word line WL may be made of or include a metal-based material, a semiconductor material, or a combination thereof. The first and second word lines G1 and G2 of the word line WL may be made of or include titanium nitride, tungsten, polysilicon, or a combination thereof. For example, the first and second word lines G1 and G2 of the word line WL may be made of or include a TiN/W stack in which titanium nitride and tungsten are sequentially stacked. The first and second word lines G1 and G2 of the word line WL may be made of or include a high work function material, a low work function material, or a combination thereof. The low work function material may have a low work function of approximately 4.5 eV or less, and the high work function material may have a high work function of approximately 4.5 eV or less. For example, the low work function material may be made of or include N-type doped polysilicon, and the high work function material may include tungsten, titanium nitride, or a combination thereof. According to another embodiment of the present invention, the first and second word lines G1 and G2 of the word line WL may have a dual work function structure combining a low work function material and a high work function material.

The cell capacitor CAP may be arranged horizontally in the second direction D2 from the transistor TR. The cell capacitor CAP may include a first storage node SN extending horizontally from the horizontal active layer ACT in the second direction D2. The cell capacitor CAP may further include a first dielectric layer DE and a first plate node PN formed over the first storage node SN. The first storage node SN, the first dielectric layer DE, and the first plate node PN may be arranged horizontally in the second direction D2. The first storage node SN may have a horizontally oriented cylindrical shape. The first dielectric layer DE may conformally cover the cylindrical inner wall and the cylindrical outer wall of the first storage node SN. The first plate node PN may have a shape extending to the cylindrical inner wall and cylindrical outer wall of the first storage node SN over the first dielectric layer DE. The first storage node SN may be electrically connected to the horizontal active layer ACT.

The first storage node SN may have a three-dimensional structure. The first storage node SN may have a horizontal three-dimensional structure which is oriented in the second direction D2. As an example of the three-dimensional structure, the first storage node SN may have a cylindrical shape. According to another embodiment of the present invention, the first storage node SN may have a pillar shape or a pylinder shape. The pylinder shape may refer to a structure in which a pillar shape and a cylindrical shape are merged.

The first storage node SN and the first plate node PN may be made of or include a noble metal, a metal nitride, a conductive metal oxide, a conductive noble metal oxide, a metal carbide, a metal silicide, or a combination thereof. For example, the first storage node SN and the first plate node PN may be made of or include titanium (Ti), titanium nitride (TiN), tantalum (Ta), tantalum nitride (TaN), tungsten (W), tungsten nitride (Wn), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, or a tungsten nitride/tungsten (WN/W) stack. The first plate node PN may include a combination of a metal-based material and a silicon-based material. For example, the first plate node PN may be a titanium nitride/silicon germanium/tungsten nitride (TiN/SiGe/WN) stack. In the titanium nitride/silicon germanium/tungsten nitride (TiN/SiGe/WN) stack, silicon germanium may be a gap-fill material that fills the inside of the cylinder of the first storage node SN over titanium nitride, and titanium nitride (TiN) may serve as the first plate node PN of the cell capacitor CAP, and tungsten nitride may be a low-resistance material.

The first dielectric layer DE may be made of or include silicon oxide, silicon nitride, a high-k material, or a combination thereof. The high-k material may have a higher dielectric constant than silicon oxide. Silicon oxide (SiO₂) may have a dielectric constant of approximately 3.9, and the first dielectric layer DE may include a high-k material with a dielectric constant of approximately 4 or more. The high-k material may have a dielectric constant of approximately 20 or more. The high-k material may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅) or strontium titanium oxide (SrTiO₃). According to another embodiment of the present invention, the first dielectric layer DE may be formed of a composite layer including two or more layers of the aforementioned high-k materials.

The first dielectric layer DE may be formed of zirconium-based oxide (Zr-based oxide). The first dielectric layer DE may have a stack structure containing at least zirconium oxide (ZrO₂). The first dielectric layer DE may include a ZA (ZrO₂/Al₂O₃) stack or a ZAZ (ZrO₂/Al₂O₃/ZrO₂) stack. The ZA stack may have a structure in which aluminum oxide (Al₂O₃) is stacked over zirconium oxide (ZrO₂). The ZAZ stack may have a structure in which zirconium oxide (ZrO₂), aluminum oxide (Al₂O₃), and zirconium oxide (ZrO₂) are sequentially stacked. The ZA stack and ZAZ stack may be referred to as a zirconium oxide-based layer (ZrO₂-based layer). According to another embodiment of the present invention, the first dielectric layer DE may be formed of hafnium-based oxide (Hf-based oxide). The first dielectric layer DE may have a stack structure containing at least hafnium oxide (HfO₂). The first dielectric layer DE may include an HA (HfO₂/Al₂O₃) stack or an HAH (HfO₂/Al₂O₃/HfO₂) stack. The HA stack may have a structure in which aluminum oxide (Al₂O₃) is stacked over hafnium oxide (HfO₂). The HAH stack may have a structure in which hafnium oxide (HfO₂), aluminum oxide (Al₂O₃), and hafnium oxide (HfO₂) are sequentially stacked. The HA stack and HAH stack may be referred to as a hafnium oxide-based layer (HfO₂-based layer). In the ZA stack, ZAZ stack, HA stack, and HAH stack, aluminum oxide (Al₂O₃) may have a greater band gap energy (which, hereinafter, may be simply referred to as band gap) than zirconium oxide (ZrO₂) and hafnium oxide (HfO2). Aluminum oxide (Al₂O₃) may have a lower dielectric constant than zirconium oxide (ZrO₂) and hafnium oxide (HfO₂). Accordingly, the first dielectric layer DE may include a stack of a high-k material and a high band gap material with a greater band gap than the high-k material. The first dielectric layer DE may be made of or include silicon oxide (SiO₂) as a high band gap material other than aluminum oxide (Al₂O₃). Since the first dielectric layer DE includes a high band gap material, leakage current may be suppressed. The high band gap material may be thinner than the high-k material. According to another embodiment of the present invention, the first dielectric layer DE may include a laminated structure in which a high-k material and a high bandgap material are alternately stacked. For example, the first dielectric layer DE may include a ZAZA (ZrO₂/Al₂O₃/ZrO₂/Al₂O₃) stack, a ZAZAZ (ZrO₂/Al₂O₃/ZrO₂/Al₂O₃/ZrO₂) stack, a HAHA (HfO₂/Al₂O₃/HfO₂/Al₂O₃) stack, or a HAHAH (HfO₂/Al₂O₃/HfO₂/Al₂O₃/HfO₂) stack. In the above laminated structure, aluminum oxide (Al₂O₃) may be thinner than zirconium oxide (ZrO₂) and hafnium oxide (HfO₂).

According to another embodiment of the present invention, the first dielectric layer DE may include a stack structure, a laminated structure, or an inter-mixing structure including zirconium oxide, hafnium oxide, and aluminum oxide.

According to another embodiment of the present invention, the first dielectric layer DE may be made of or include a ferroelectric material or an anti-ferroelectric material. The ferroelectric material may include HfZrO, HfSiO, or a combination thereof. Each of the cell capacitors CAP and the reservoir capacitors RCAP may be made of or include a ferroelectric capacitor.

According to another embodiment of the present invention, an interface control layer for improving leakage current may be further formed between the first storage node SN and the first dielectric layer DE. The interface control layer may be made of or include titanium oxide (TiO₂), niobium oxide, or niobium nitride. The interface control layer may also be formed between the first plate node PN and the first dielectric layer DE.

The cell capacitor CAP may include a metal-insulator-metal (MIM) capacitor. The first storage node SN and the first plate node PN may be made of or include a metal based material.

A storage contact node SNC may be formed between the first storage node SN and the second source/drain region SR. The storage contact node SNC may be coupled to the second source/drain region SR. The storage contact node SNC may be made of or include a conductive material. The storage contact node SNC may be made of or include a silicon, a silicon-based material, a metal-based material, or a combination thereof. The storage contact node SNC may be made of or include silicon, a metal, a metal nitride, a metal silicide, or a combination thereof. The storage contact node SNC may be made of or include polysilicon, titanium nitride, tungsten, or a combination thereof. For example, the storage contact node SNC may be made of or include polysilicon (N-type doped polysilicon) or titanium nitride (TiN) that is doped with an N-type impurity.

The first source/drain region DR may include impurities diffused from the bit line contact node BLC, and the second source/drain region SR may include impurities diffused from the storage contact node SNC.

The reservoir capacitor array CAR may include horizontal conductive layers LCL that are coupled to the reservoir capacitors RCAP. The horizontal conductive layers LCL may be referred to as “horizontal portions LCL”. Whereas the memory cell array MCA includes the word line WL extending in a direction intersecting with each of the horizontal active layers ACT, the reservoir capacitor array CAR may not include a material intersecting with the horizontal conductive layers ACT. The reservoir capacitor array CAR may be word line-free or transistor-free.

The reservoir capacitors RCAP may be respectively coupled to first sides of the horizontal conductive layers LCL. The second sides of the horizontal conductive layers LCL may be coupled to a vertical conductive line VCL. The vertical conductive line VCL may extend in the first direction D1. The vertical conductive line VCL may include a pillar portion VP, a plurality of extension portions VE, and a plurality of electrode portions VN. A first contact node CN1 may be formed between the vertical conductive line VCL and the horizontal conductive layer LCL. A second contact node CN2 may be formed between the horizontal conductive layer LCL and the reservoir capacitors RCAP.

The horizontal conductive layers LCL may be made of or include a semiconductor material. The horizontal conductive layers LCL may be made of or include a silicon-containing layer or a silicon germanium-containing layer. For example, the horizontal conductive layers LCL may be made of or include silicon, monocrystalline silicon, doped polysilicon, undoped polysilicon, amorphous silicon, silicon germanium, or a combination thereof. According to another embodiment of the present invention, the horizontal conductive layers LCL may be made of or include nano-wires or nano sheets. The nano-wires and nano sheets may be formed of or include a semiconductor material. According to another embodiment of the present invention, the horizontal conductive layers LCL may be made of or include an oxide semiconductor material.

The horizontal conductive layers LCL may be doped. The conductive layers LCL may be doped with an N-type impurity or P-type impurities. For example, the horizontal conductive layers LCL may be doped with at least one impurity selected among arsenic (As), phosphorus (P), boron (B), indium (In), and combinations thereof. The horizontal conductive layers LCL may be a silicon material that is doped with an N-type impurity. The horizontal conductive layers LCL may be polysilicon that is doped with an N-type impurity. The horizontal conductive layers LCL may be one impurity region. According to another embodiment of the present invention, the horizontal conductive layers LCL may have a structure in which two impurity regions contact each other.

The length of the horizontal conductive layer LCL may be shorter than the length of the horizontal active layer ACT. Unlike the horizontal active layer ACT, the horizontal conductive layer LCL may not include a channel CH, so it may be as short as a length obtained by subtracting the length of the channel CH from the total length of the horizontal active layer ACT. The horizontal conductive layer LCL may have a length where doped regions into which impurities are diffused from the first and second contact nodes CN1 and CN2 contacting both ends contact each other. The length of the horizontal conductive layer LCL may be adjusted in such a manner that the doped regions into which the impurities are diffused from both ends contact each other so that the entire horizontal conductive layer LCL is conductive.

According to another embodiment of the present invention, referring to FIG. 3, the reservoir capacitor array of the semiconductor device 200 may include a horizontal conductive layer LCL, a reservoir capacitor RCAP, and a vertical conductive line VCL arranged along the second direction with the horizontal conductive layer LCL between the reservoir capacitor RCAP and the vertical conductive line VCL. The horizontal conductive layer LCL may be made of or include a metal based material. For example, the horizontal conductive layer LCL may be made of or include tungsten (W).

The vertical conductive line VCL may be vertically oriented in the first direction D1. The vertical conductive line VCL may be referred to as a vertically oriented conductive line or a pillar-type conductive line. The vertical conductive line VCL may include a pillar portion VP and extension portions VE. The pillar portion VP of the vertical conductive line VCL may be vertically oriented in the first direction D1. The extension portions VE may extend from the pillar portion VP in the second direction D2. Electrode portions VN may cover a portion of the extension portions VE. In particular, according to this embodiment of the present invention, the electrode portions VN may have the same structure as that of the storage node SN of the reservoir capacitor RCAP and may be symmetrical bilaterally with the storage node SN of the opposing reservoir capacitor RCAP.

The vertical conductive line VCL may be made of or include a conductive material. The vertical conductive line VCL may be made of or include a silicon, —a silicon-based material, a metal-based material, or a combination thereof. The vertical conductive line VCL may be made of or include silicon, a metal, a metal nitride, a metal silicide, or a combination thereof. The vertical conductive line VCL may be made of or include polysilicon, titanium nitride, tungsten, or a combination thereof. For example, the vertical conductive line VCL may be made of or include polysilicon or titanium nitride (TiN) that is doped with an N-type impurity. The vertical conductive line VCL may be made of or include a TiN/W stack. The TiN/W stack may be a layer of titanium nitride and a layer of tungsten formed on the layer of the titanium nitride. The pillar portion VP and the extension portions VE of the vertical conductive line VCL may be formed of the same material. The pillar portion VP and the extension portions VE of the vertical conductive line VCL may have a singular integrated structure made of the same material and no interfaces between the pillar portion and the extension portions. The electrode portion VN of the vertical conductive line VCL may be in direct contact with the pillar portion VP and the extension portions VE of the vertical conductive line VCL. The electrode portion VN of the vertical conductive line VCL may be formed simultaneously with the storage node SN of the reservoir capacitor RCAP. The electrode portion VN may be made of a material that is different of the material of the vertical conductive line VCL and, thus, may have a structure that is distinct from the pillar portion VP and the extension portion VE of the VCL.

The first contact node CN1 may be coupled to a first side of the horizontal conductive layer LCL. The first contact node CN1 may be made of or include a conductive material. The first contact node CN1 may be made of or include a silicon-based material, a metal-based material, or a combination thereof. The first contact node CN1 may be made of or include silicon, a metal, a metal nitride, a metal silicide, or a combination thereof. The first contact node CN1 may be made of or include polysilicon, titanium nitride, tungsten, or a combination thereof. For example, the first contact node CN1 may be made of or include polysilicon that is doped with an N-type impurity (N-type doped polysilicon). The vertical conductive line VCL may be made of or include a TiN/W stack including a layer of titanium nitride and a layer of tungsten on the titanium nitride, and the first contact node CN1 may be made of or include N-type doped polysilicon.

The reservoir capacitor RCAP may be formed to have the same structure and the same material as those of the capacitor CAP of the memory cell array MCA.

The reservoir capacitor RCAP may be disposed horizontally in the second direction D2 from the horizontal conductive layer LCL. The reservoir capacitor RCAP may include a second storage node SN1 extending horizontally from the horizontal conductive layer LCL in the second direction D2. The reservoir capacitor RCAP may further include a second dielectric layer DE1 and a second plate node PN1 over the second storage node SN1. The second storage node SN1 of the reservoir capacitor RCAP may have the same structure and may be formed of the same material as those of the electrode portion VN of the vertical conductive line VCL.

The second storage node SN1, the second dielectric layer DE1, and the second plate node PN1 may be arranged horizontally in the second direction D2. The second storage node SN1 may have a horizontally oriented cylindrical shape. The second dielectric layer DE1 may conformally cover the cylindrical inner wall and the cylindrical outer wall of the second storage node SN1. The second plate node PN1 may have a shape extending into the cylindrical inner wall and also over the cylindrical outer wall of the second storage node SN1 over the second dielectric layer DE1. The second plate node PN1 may be formed conformally on the second dielectric layer DE1. Hence, the second plate node PN1 may be in direct contact with the second dielectric layer DE1. The second storage node SN1 may be electrically connected to the horizontal conductive layer LCL. According to this embodiment of the present invention, the electrode portion VN of the vertical conductive line VCL may have the same structure (i.e., shape and material) as that of the second storage node SN1 of the reservoir capacitor RCAP, that is, a horizontally oriented cylindrical shape.

The second storage node SN1 may have a three-dimensional structure, and the second storage node SN1 may have a horizontal three-dimensional structure that is oriented in the second direction D2. As an example of a three-dimensional structure, the second storage node SN1 may have a cylindrical shape. According to another embodiment of the present invention, the second storage node SN1 may have a pillar shape or a pylinder shape. The pylinder shape may refer to a structure in which a pillar shape and a cylindrical shape are merged.

The second storage node SN1 and the second plate node PN1 may be made of or include a noble metal, a metal nitride, a conductive metal oxide, a conductive noble metal oxide, a metal carbide, a metal silicide, or a combination thereof. For example, the second storage node SN1 and the second plate node PN1 may be made of or include titanium (Ti), titanium nitride (TiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, or a tungsten nitride/tungsten (WN/W) stack. For example, the second plate node PN1 may be a stack of titanium nitride/silicon germanium/tungsten nitride (TiN/SiGe/WN). In the titanium nitride/silicon germanium/tungsten nitride (TiN/SiGe/WN) stack, silicon germanium may be a gap-fill material that fills the inside of the cylinder of the second storage node SN1 over titanium nitride, and tungsten nitride may be a low-resistance material.

The second dielectric layer DE1 may be made of or include silicon oxide, silicon nitride, a high-k material, or a combination thereof. The high-k material may have a higher dielectric constant than silicon oxide. Silicon oxide (SiO₂) may have a dielectric constant of approximately 3.9, and the second dielectric layer DE1 may include a high-k material having a dielectric constant of approximately 4 or more. The high-k material may have a dielectric constant of approximately 20 or more. The high-k material may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅) or strontium titanium oxide (SrTiO₃). According to another embodiment of the present invention, the second dielectric layer DE1 may be formed of a composite layer including two or more layers of the aforementioned high-k materials.

The second dielectric layer DE1 may be formed of zirconium-based oxide (Zr-based oxide). The second dielectric layer DE1 may have a stack structure containing at least zirconium oxide (ZrO₂). The second dielectric layer DE1 may include a ZA (ZrO₂/Al₂O₃) stack or a ZAZ (ZrO₂/Al₂O₃/ZrO₂) stack. The ZA stack may have a structure in which aluminum oxide (Al₂O₃) is stacked over zirconium oxide (ZrO₂). The ZAZ stack may have a structure in which zirconium oxide (ZrO₂), aluminum oxide (Al₂O₃), and zirconium oxide (ZrO₂) are sequentially stacked. The ZA stack and the ZAZ stack may be referred to as a zirconium oxide-based layer (ZrO₂-based layer). According to another embodiment of the present invention, the second dielectric layer DE1 may be formed of hafnium-based oxide (Hf-based oxide). The second dielectric layer DE1 may have a stack structure containing at least hafnium oxide (HfO₂). The second dielectric layer DE1 may include an HA (HfO₂/Al₂O₃) stack or an HAH (HfO₂/Al₂O₃/HfO₂) stack. The HA stack may have a structure in which aluminum oxide (Al₂O₃) is stacked over hafnium oxide (HfO₂). The HAH stack may have a structure in which hafnium oxide (HfO₂), aluminum oxide (Al₂O₃), and hafnium oxide (HfO₂) are sequentially stacked. The HA stack and the HAH stack may be referred to as a hafnium oxide-based layer (HfO₂-based layer). In the ZA stack, ZAZ stack, HA stack, and HAH stack, aluminum oxide (Al₂O₃) may have a greater band gap energy (which, hereinafter, may be simply referred to as band gap) than zirconium oxide (ZrO₂) and hafnium oxide (HfO₂). Aluminum oxide (Al₂O₃) may have a lower dielectric constant than zirconium oxide (ZrO₂) and hafnium oxide (HfO₂). Accordingly, the second dielectric layer DE1 may include a stack of a high-k material and a high band gap material with a greater band gap than the high-k material. The second dielectric layer DE1 may include silicon oxide (SiO₂) as a high band gap material other than aluminum oxide (Al₂O₃). As the second dielectric layer DE1 includes a high band gap material, leakage current may be suppressed. The high band gap material may be thinner than the high-k material. According to another embodiment of the present invention, the second dielectric layer DE1 may include a laminated structure in which the high-k material and the high bandgap material are alternately stacked. For example, the second dielectric layer DE1 may include a ZAZA (ZrO₂/Al₂O₃/ZrO₂/Al₂O₃) stack, a ZAZAZ (ZrO₂/Al₂O₃/ZrO₂/Al₂O₃/ZrO₂) stack, a HAHA (HfO₂/Al₂O₃/HfO₂/Al₂O₃) stack, or a HAHAH (HfO₂/Al₂O₃/HfO₂/Al₂O₃/HfO₂) stack. In the above laminated structure, aluminum oxide (Al₂O₃) may be thinner than zirconium oxide (ZrO₂) and hafnium oxide (HfO₂).

According to another embodiment of the present invention, the second dielectric layer DE1 may include a stack structure, a laminated structure, or an inter-mixing structure including zirconium oxide, hafnium oxide, and aluminum oxide.

According to another embodiment of the present invention, the second dielectric layer DE1 may be made or include a ferroelectric material or an anti-ferroelectric material. The ferroelectric material may include HfZrO, HfSiO, or a combination thereof. The cell capacitors CAP and the reservoir capacitors RCAP may be ferroelectric capacitors.

According to another embodiment of the present invention, an interface control layer for improving leakage current may be further formed between the second storage node SN1 and the second dielectric layer DE1. The interface control layer may be made of or include titanium oxide (TiO₂), niobium oxide, or niobium nitride. The interface control layer may also be formed between the second plate node PN1 and the second dielectric layer DE1.

The reservoir capacitor RCAP may include a MIM (metal-insulator-metal) capacitor. The second storage node SN1 and the second plate node PN1 may be made of or include a metal based material.

A second contact node CN2 may be formed between the second storage node SN1 and the horizontal conductive layer LCL. The second contact node CN2 may be coupled to the second side of the horizontal conductive layer LCL. The second contact node CN2 may be made of or include a conductive material. The second contact node CN2 may be made of or include a silicon-based material, a metal-based material, or a combination thereof. The second contact node CN2 may be made of or include silicon, a metal, a metal nitride, a metal silicide, or a combination thereof. The second contact node CN2 may be made of or include polysilicon, titanium nitride, tungsten, or a combination thereof. For example, the second contact node CN2 may be made of or include polysilicon that is doped with an N-type impurity (N-type doped polysilicon).

According to another embodiment of the present invention, the reservoir capacitor RCAP and the vertical conductive line VCL may directly contact the horizontal conductive layer LCL without the presence of the first and second contact nodes CN1 and CN2.

The semiconductor device 100 of FIGS. 1 and 2 may be, for example, a Dynamic Random Access Memory (DRAM) or a ferroelectric memory (FeRAM).

According to other embodiments of the present invention, the cell capacitor CAP and the reservoir capacitor RCAP may be replaced with other data storage structures or materials, such as, for example, a phase change material, a Magnetic Tunnel Junction (MTJ), or a variable resistance material.

Horizontal active layers ACT that are adjacent to each other in the first direction D1 may contact one bit line BL. Horizontal active layers ACT disposed adjacent to each other in the third direction D3 may share the word line WL.

In the memory cell array MCA, a plurality of word lines WL may be vertically stacked in the first direction D1. Each word line WL may include a pair of a first word line G1 and a second word line G2. A plurality of horizontal active layers ACT may be arranged horizontally spaced apart from each other in the second direction D2 between the first word line G1 and the second word line G2. According to another embodiment of the present invention, the word line WL may be replaced with a single word line structure formed of only the first word line G1 or the second word line G2.

The lower structure LS may be a material suitable for semiconductor processing. The lower structure LS may include at least one of a conductive material, a dielectric material, and a semiconductive material. The lower structure LS may be made of or include a semiconductor substrate, and the semiconductor substrate may be formed of a material containing silicon. The lower structure LS may be made of or include silicon, monocrystalline silicon, polysilicon, amorphous silicon, silicon germanium, monocrystalline silicon germanium, polycrystalline silicon germanium, carbon-doped silicon, combinations thereof, and multilayers thereof. The lower structure LS may also be made of or include other semiconductor materials, such as germanium. The lower structure LS may be made of or include a III/V-group semiconductor substrate, for example, a compound semiconductor substrate, such as GaAs. The lower structure LS may be made of or include a silicon-on-insulator (SOI) substrate.

According to another embodiment of the present invention, the lower structure LS may include peripheral circuits. The peripheral circuits may include a plurality of peripheral circuit transistors. The peripheral circuits may be disposed at a lower level than the memory cell array MCA and the reservoir capacitor array CAR. This may be referred to as PUC (Peripheral Circuits-Under-Cell) structure. The peripheral circuits may include at least one control circuit for driving the memory cell array MCA and the reservoir capacitor array CAR. The lower structure LS may be referred to as “a first peripheral circuit” and the reservoir capacitor array CAR may be referred to as “a second peripheral circuit”. The at least one control circuit or more of the peripheral circuits may include an N-channel transistor, a P-channel transistor, a CMOS circuit, or a combination thereof. The at least one control circuit of the peripheral circuit portion PERI may include an address decoder circuit, a read circuit, a write circuit, and the like. The at least one control circuit of the peripheral circuits may include a planar channel transistor, a recess channel transistor, a buried gate transistor, a fin channel transistor (FinFET), and the like.

For example, the peripheral circuits may include sub-word line drivers SWD, a sense amplifier SA, and a reservoir capacitor control circuit CL_RCAP. The word lines WL may be coupled to sub-word line drivers SWD. The bit lines BL may be coupled to the sense amplifier SA. The reservoir capacitors RCAP may be coupled to the reservoir capacitor control circuit CL_RCAP.

According to another embodiment of the present invention, referring to FIG. 4, the lower structure LS of the semiconductor device 300 may be disposed at a higher level than the reservoir capacitor array CAR. This may be referred to as POC (Peripheral Circuit-Over-Cell) structure. In the POC structure, peripheral circuits may be disposed at a higher level than the reservoir capacitor array CAR. Although not illustrated, the lower structure LS may be disposed at a higher level than the memory cell array CAR, which is disposed at the same level as the reservoir capacitor array CAR.

According to another embodiment of the present invention, the lower structure LS may be referred to as a first peripheral circuit portion, and the reservoir capacitor array CAR may be referred to as a second peripheral circuit portion. Accordingly, the first peripheral circuit portion may be disposed at a lower level than the memory cell array MCA, and the second peripheral circuit portion may be disposed horizontally from the memory cell array MCA. The first peripheral circuit portion may include control circuits such as a sense amplifier and a sub-word line driver for controlling the memory cell array MCA. The second peripheral circuit portion may include a reservoir capacitor array CAR, and the control circuits for controlling the reservoir capacitor array CAR may be disposed in the first peripheral circuit portion.

The components of the cell capacitors CAP and the components of the reservoir capacitors RCAP may have the same shape and may be formed of the same material. For example, the first storage nodes SN of the cell capacitors CAP and the second storage nodes SN1 of the reservoir capacitors RCAP may have a cylindrical shape.

The bit line BL of the memory cell array MCA and the vertical conductive line VCL of the reservoir capacitor array CAR may be formed of the same material.

The bit line contact node BLC of the memory cell array MCA and the first contact node CN1 of the reservoir capacitor array CAR may have the same shape and may be formed of the same material.

The storage contact node SNC of the memory cell array MCA and the second contact node CN2 of the reservoir capacitor array CAR may have the same shape and may be formed of the same material.

The memory cell array MCA and the reservoir capacitor array CAR may have similar components except for the word line WL. The memory cell array MCA may include a word line WL, and the reservoir capacitor array CAR may be word line-free.

According to the above-described embodiment of the present invention, the bias of VPP, etc., may be stabilized by forming the reservoir capacitors RCAP.

Also, since a three-dimensional array of reservoir capacitors is formed horizontally from the memory cell array in the same structure as that of the cell capacitors of the memory cell array, the capacitance of the reservoir capacitors may be increased by securing the area of the reservoir capacitors.

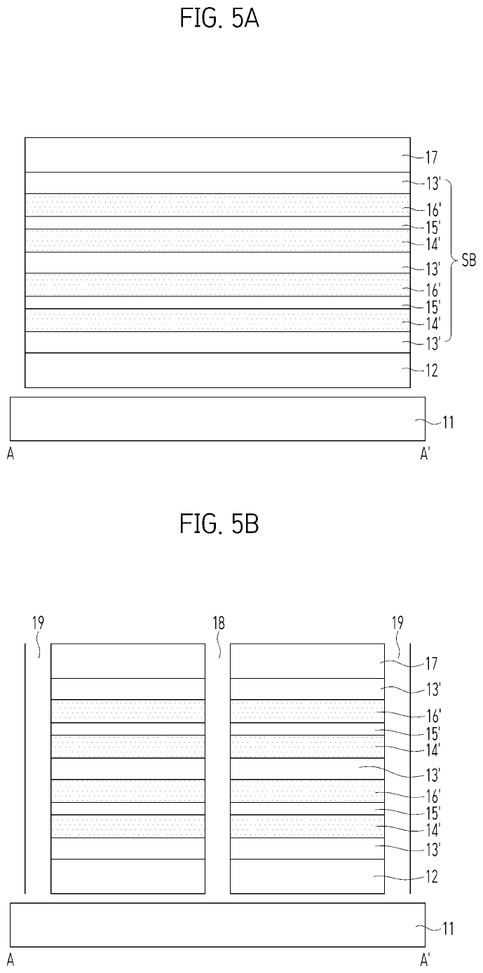

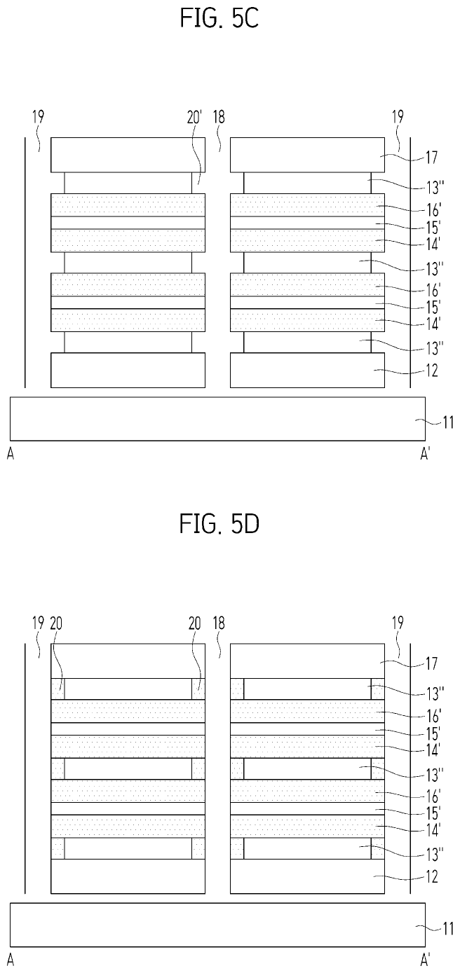

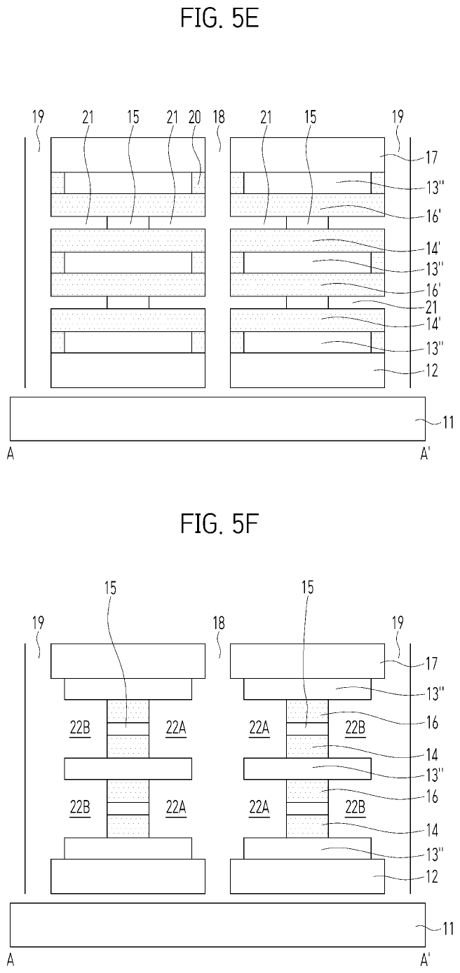

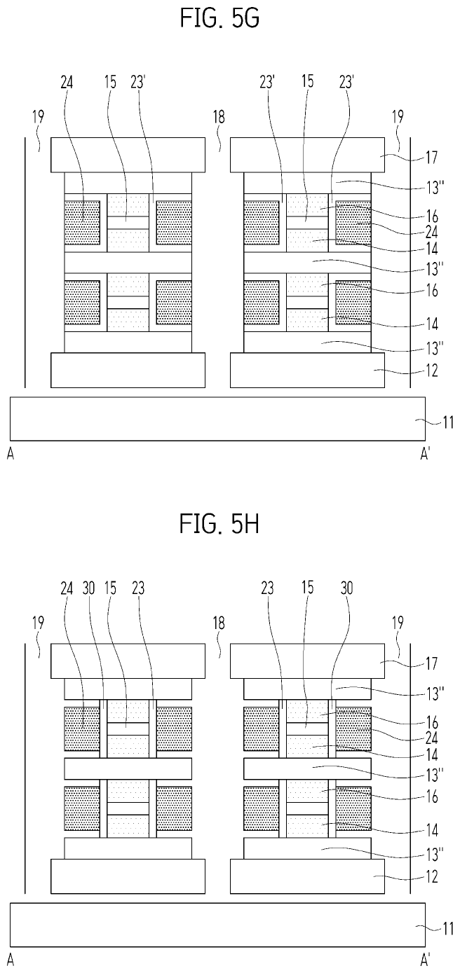

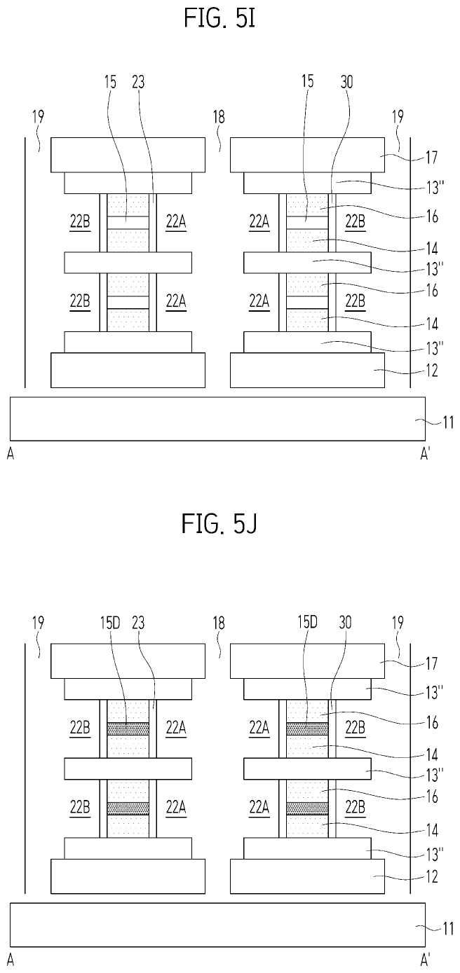

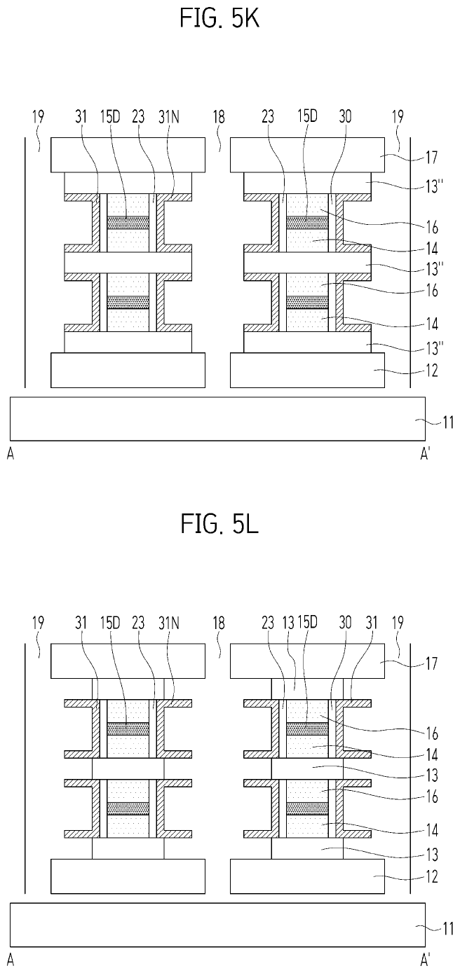

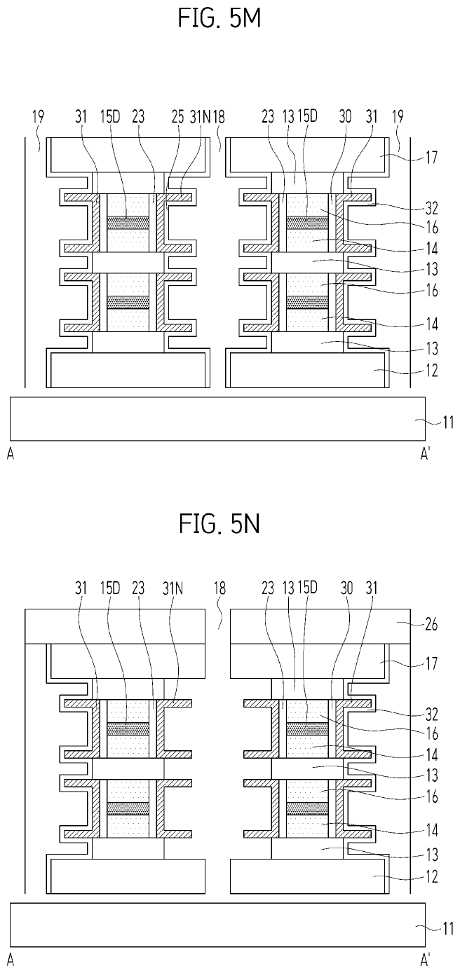

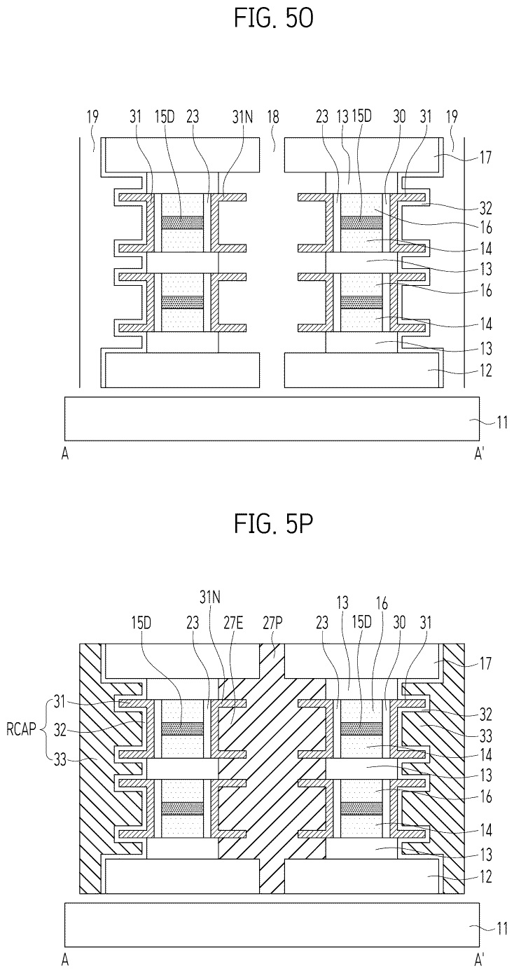

FIGS. 5A to 5P are cross-sectional views illustrating a method for fabricating a semiconductor device in accordance with an embodiment of the present invention. FIGS. 5A to 5P illustrate a method of forming the reservoir capacitor array CAR illustrated in FIGS. 1 and 2.

Referring to FIG. 5A, an inter-layer dielectric layer 12 may be formed over the lower structure 11, and a stack body SB may be formed over the inter-layer dielectric layer 12. The stack body SB may be formed by repeatedly stacking sub-stacks each of which includes a dielectric layer 13′, a first sacrificial layer 14′, a semiconductor layer 15′, and a second sacrificial layer 16′ in the mentioned order. For example, the dielectric layer 13′ may be silicon oxide, and the first and second sacrificial layers 14′ and 16′ may be silicon nitride. For example, the semiconductor layer 15′ may be a silicon layer, a monocrystalline silicon layer, or a polysilicon layer. The uppermost layer of the stack body SB may be the dielectric layer 13′. According to another embodiment of the present invention, the semiconductor layer 15′ may be made of or include an oxide semiconductor material.

A hard mask layer 17 may be formed over the stack body SB. The hard mask layer 17 may be made of or include a material having an etch selectivity with respect to the dielectric layer 13′, the first sacrificial layer 14′, the semiconductor layer 15′, and the second sacrificial layer 16′ that form the stack body SB. The hard mask layer 17 may be made of or include SiCO, for example.

The lower structure 11 may be made of or include a semiconductor substrate or peripheral circuits. The inter-layer dielectric layer 12 may be made of or include silicon oxide, silicon nitride, or a combination thereof.

Referring to FIG. 5B, a plurality of openings 18 and 19 may be formed in the stack body SB. The openings 18 and 19 may have a hole shape. To form the openings 18 and 19, the hard mask layer 17 may be etched using a mask pattern (not shown), and the stack body SB may be etched using the hard mask layer 17, and the inter-layer dielectric layer 12 may be etched successively. The openings 18 and 19 may include a first opening 18 and a second opening 19. The first opening 18 and the second opening 19 may have the same size or may have different sizes.

The mask pattern (not shown) for forming the first opening 18 and the second opening 19 may be a mask pattern for forming a bit line contact and a storage node contact in the memory cell area. Since the mask pattern for forming the first and second openings 18 and 19 may be formed using the same pattern (also referred to as a reticle) as that of the mask pattern in the memory cell area, formation of an additional reticle may be omitted.

Referring to FIG. 5C, the dielectric layers 13′ may be partially recessed through the first and second openings 18 and 19. For example, partial etching of the dielectric layers 13′ may be performed. As a result of the partial etching of the dielectric layers 13′, dielectric layer patterns 13″ may be formed with sacrificial recesses 20′ also formed on both sides of the dielectric layer patterns 13″.

Referring to FIG. 5D, sacrificial capping layers 20 may be formed to fill the sacrificial recesses 20′. The sacrificial capping layers 20 may be formed of the same material as those of the first and second sacrificial layers 14′ and 16′. The sacrificial capping layers 20 may be, for example, silicon nitride. The sacrificial capping layers 20 may not fill the first and second openings 18 and 19.

Referring to FIG. 5E, the semiconductor layers 15′ may be horizontally recessed through the first and second openings 18 and 19. Accordingly, semiconductor layer patterns 15 may be formed with horizontal recesses 21 also formed on both sides of the semiconductor layer patterns 15. While the semiconductor layer patterns 15 are formed, the sacrificial capping layers 20 and the first and second sacrificial layer patterns 14′ and 16′ may not be lost. The length of the semiconductor layer patterns 15 may be shorter than the length of the horizontal active layer ACT (see FIG. 1) of the memory cell.

Referring to FIG. 5F, expanded horizontal recesses 22A and 22B may be formed. To form the expanded horizontal recesses 22A and 22B, the sacrificial capping layers 20 and the first and second sacrificial layers 14′ and 16′ may be partially etched. While the sacrificial capping layers 20 and the first and second sacrificial layers 14′ and 16′ are etched, the dielectric layer patterns 13″ may not be etched. First and second horizontal insulating lines 14 and 16 may be formed in the upper and lower portions of the semiconductor layer patterns 15, respectively, by partially etching the first and second sacrificial layers 14′ and 16′. The horizontal lengths of the first and second horizontal insulating lines 14 and 16 may be equal to the horizontal lengths of the semiconductor layer patterns 15.

Referring to FIG. 5G, a preliminary contact layer 23′ may be formed to cover the inner walls of the expanded horizontal recesses 22A and 22B (see FIG. 5F). The preliminary contact layer 23′ may be formed to be separated from each other by the dielectric layer patterns 13″. The preliminary contact layer 23′ may contact both ends of the semiconductor layer patterns 15. For example, the preliminary contact layer 23′ may be made of or include polysilicon that is doped with an N-type impurity.

Subsequently, a third sacrificial layer 24 may be formed to fill the expanded horizontal recesses 22A and 22B (see FIG. 5F) over the preliminary contact layer 23′. The third sacrificial layer 24 may include a material having an etch selectivity with respect to the dielectric layer patterns 13″ and the preliminary contact layer 23′. The third sacrificial layer 24 may include, for example, silicon nitride. Referring to FIG. 5H, the preliminary contact layer 23′ interposed between the dielectric layer patterns 13″ and the third sacrificial layer 24 may be etched. As the preliminary contact layer 23′ interposed between the dielectric layer patterns 13″ and the third sacrificial layer 24 is etched, the first and second contact nodes 23 and 30 respectively contacting both ends of the semiconductor layer patterns 15 may be formed. The first and second contact nodes 23 and 30 may be separated from each other by the dielectric layer patterns 13″.

Referring to FIG. 5I, the third sacrificial layer 24 (see FIG. 5H) may be removed. As the third sacrificial layer 24 (see FIG. 5H) is removed, the first and second contact nodes 23 and 30 respectively contacting both ends of the semiconductor layer patterns 15 may be exposed.

Referring to FIG. 5J, the semiconductor layer patterns 15 may be replaced with horizontal conductive layers 15D. The horizontal conductive layers 15D may be doped with an impurity. For example, the horizontal conductive layers 15D may be doped with the impurity diffused from the first and second contact nodes 23 and 30. To form the horizontal conductive layers 15D, the semiconductor layer patterns 15 may be thermally treated at an effective temperature to cause the impurity from the first and second contact nodes 23 and 30 to diffuse into the horizontal conductive layer 15D. When the first and second contact nodes 23 and 30 include polysilicon that is doped with an N-type impurity, the horizontal conductive layers 15D may become doped regions with the N-type impurity. The horizontal conductive layers 15D may contact the doped regions into which the impurities are diffused from the first and second contact nodes 23 and 30 so that the entire horizontal conductive layers 15D may be replaced with the doped region.

Referring to FIG. 5K, an electrode portion 31N of the vertical conductive line and a storage node 31 of the reservoir capacitor may be formed over the first contact node 23 and the second contact node 30, respectively. The electrode portion 31N of the vertical conductive line and the storage node 31 of the reservoir capacitor may conformally cover the expanded horizontal recesses 22A and 22B (see FIG. 5J).

The electrode portion 31N of the vertical conductive line may be coupled to the horizontal conductive layer 15D through the first contact node 23. The storage node 31 of the reservoir capacitor may be coupled to the horizontal conductive layer 15D through the second contact node 30.

The electrode portion 31N of the vertical conductive line and the storage node 31 of the reservoir capacitor may be formed in a symmetrical structure. The electrode portion 31N of the vertical conductive line and the storage node 31 of the reservoir capacitor that are facing each other may have a bilaterally symmetrical structure.

Referring to FIG. 5L, the dielectric layer patterns 13″ (see FIG. 5K) may be horizontally recessed through the first and second openings 18 and 19. A separation portion 13 may be formed by partially etching the dielectric layer patterns 13″ (see FIG. 4K).

At the same time, the electrode portion 31N of the vertical conductive line and the storage node 31 of the reservoir capacitor may have the outer wall exposed to form a cylindrical shape. The electrode portion 31N of the vertical conductive line and the storage node 31 of the reservoir capacitor that are facing each other may have a cylindrical shape of a symmetrical structure.

Referring to FIG. 5M, a fourth sacrificial layer 25 and a dielectric layer 31 may be formed to cover the entire surface including the electrode portion 31N of the vertical conductive line and the storage node 31 of the reservoir capacitor.

Referring to FIG. 5N, a mask pattern 26 that opens the first opening 18 may be formed over the hard mask layer 17.

Subsequently, the fourth sacrificial layer 25 in the first opening 18 may be removed. As a result, the electrode portion 31N of the vertical conductive line having a cylindrical shape may be exposed in the first opening 18.

Referring to FIG. 5O, the mask pattern 26 (see FIG. 5N) may be removed. When the mask pattern 26 is formed of a photoresist, the mask pattern 26 may be removed through an oxygen stripping process.

Referring to FIG. 5P, a pillar portion 27P and an extension portion 27E of the vertical conductive line filling the first opening 18 over the electrode portion 31N of the vertical conductive line and a plate node 33 filling the second opening 19 over the storage node 31 of the reservoir capacitor may be formed.

Accordingly, the vertical conductive line in which the electrode portion 31N, the extension portion 27E, and the pillar portion 27P are stacked may be formed in the first opening 18 (see FIG. 5O), and the reservoir capacitor RCAP in which the storage node 31, the dielectric layer 32, and the plate node 33 are stacked may be formed in the second opening 19 (see FIG. 5O).

As described above, according to this embodiment of the present invention, the line width of the semiconductor layer pattern 15 may be reduced by performing the recess process for forming the semiconductor layer pattern 15 on both sides through the first and second openings 18 and 19. As a result, the horizontal conductive layer 15D may be formed and the MIM structure may be formed due to the impurities diffused through the first and second contact nodes CN1 and CN2.

Also, the recess process for forming the separation portion 13 may be performed on both sides through the first and second openings 18 and 19 to increase the volume of the vertical conductive line and to decrease the resistance of the vertical conductive line.

Also, since the first and second openings 18 and 19 are formed using a mask pattern applying the same reticle as the reticle for forming the bit line contact and the storage node contact of the memory cell, most processes including the semiconductor layer pattern 15 may be performed with the first and second openings 18 and 19 open at the same time. Thus, it is possible to form an MIM structure and secure process margins only with a reticle for forming a memory cell array without forming an additional reticle for the reservoir capacitor.

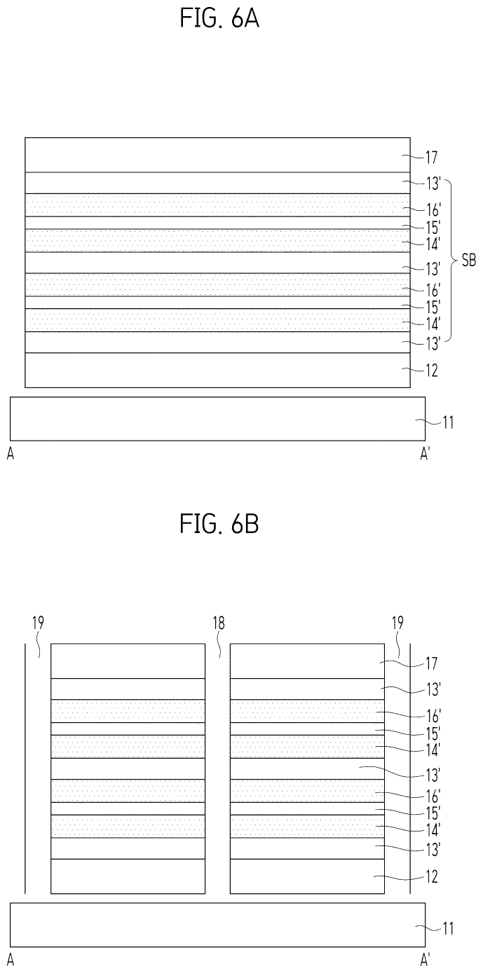

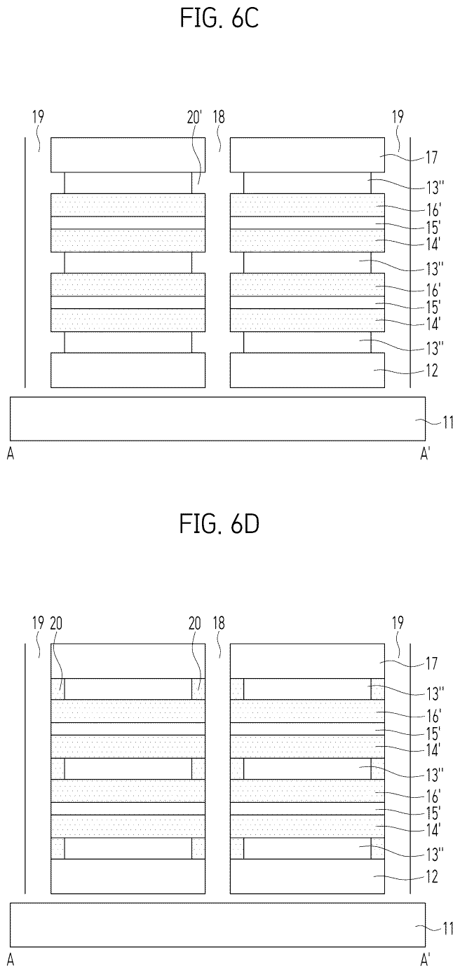

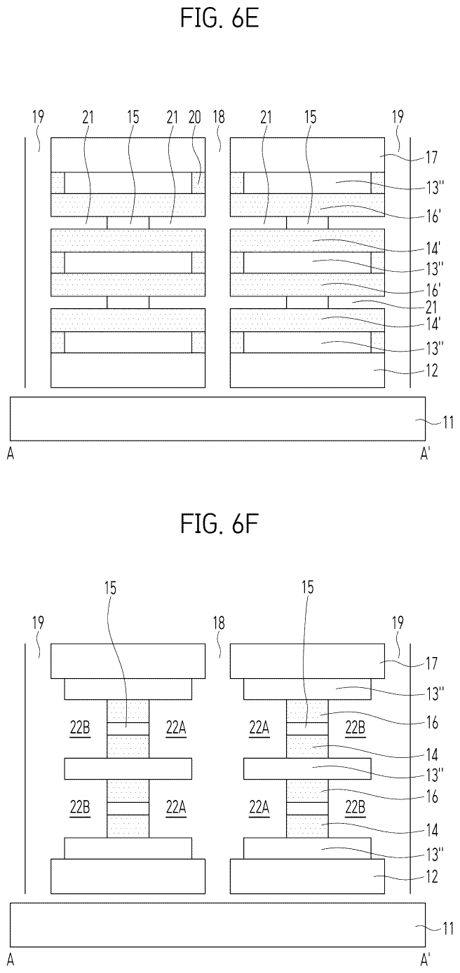

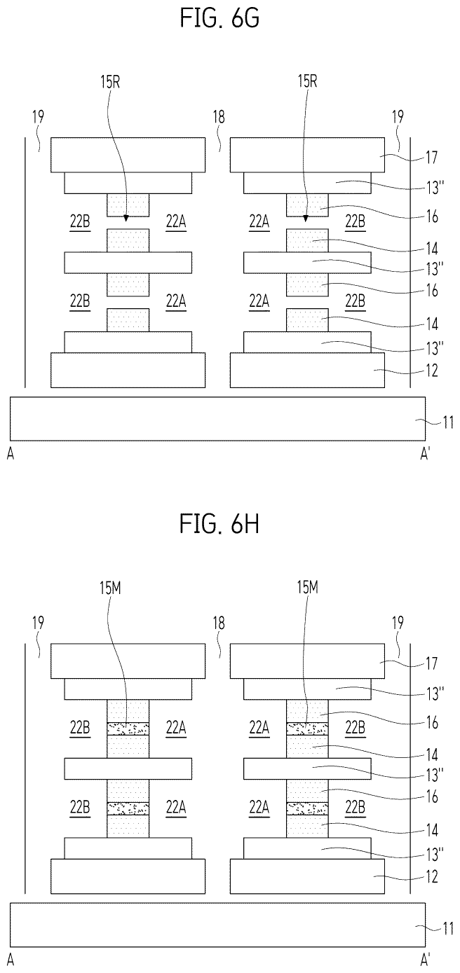

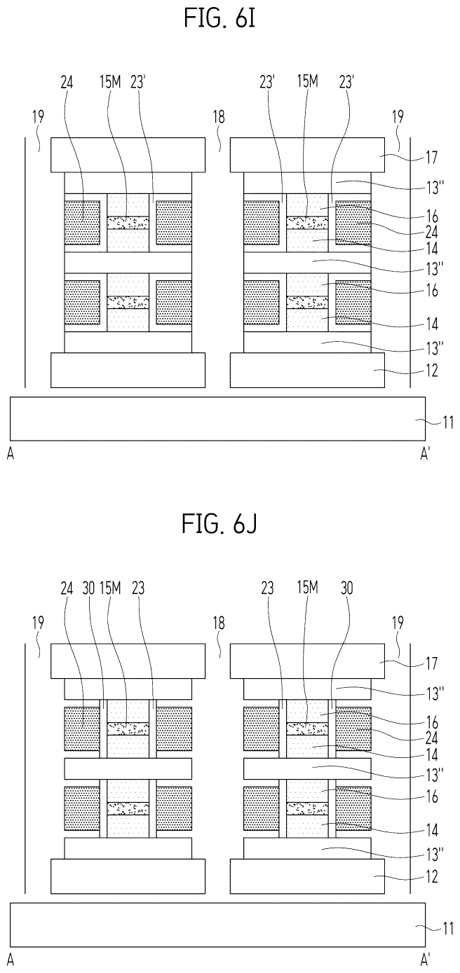

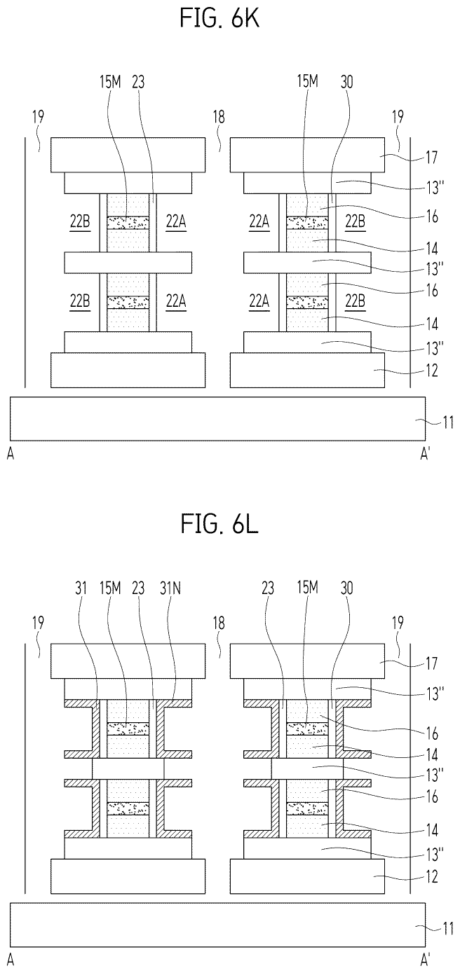

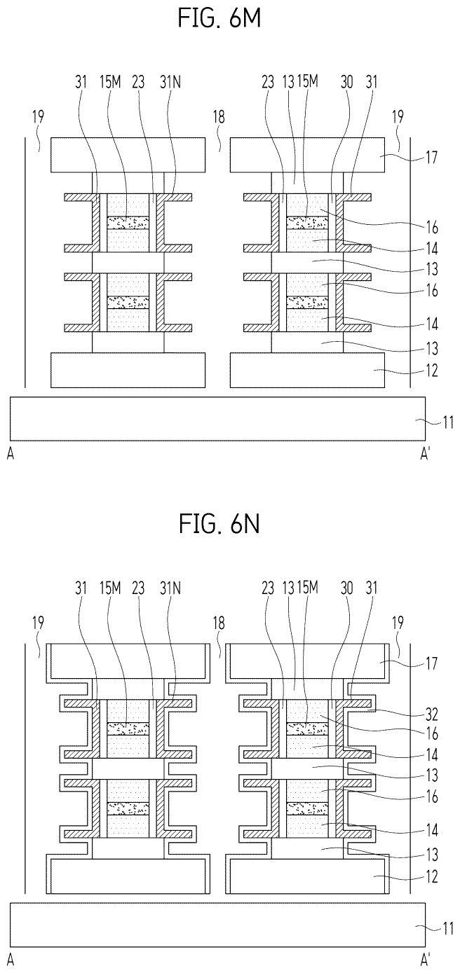

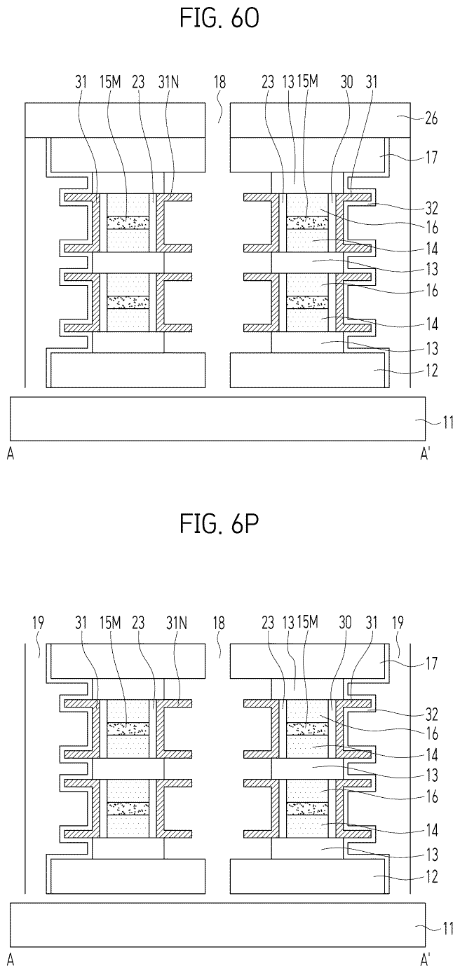

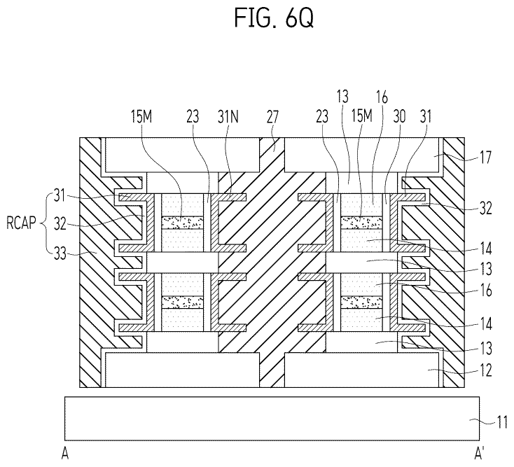

FIGS. 6A to 6Q are cross-sectional views illustrating a method for fabricating a semiconductor device in accordance with another embodiment of the present invention. FIGS. 6A to 6Q illustrate a method of forming the reservoir capacitor array CAR illustrated in FIG. 3.

The processes of FIGS. 6A to 6F may be performed in the same manner as those of FIGS. 5A to 5F, therefore a description of them will be omitted herein.

Referring to FIG. 6G, recesses 15R may be formed by removing the semiconductor layer patterns 15 (see FIG. 6F).

Referring to FIG. 6H, horizontal metal conductive layers 15M may be formed by gap-filling each recess 15R with a conductive material. The horizontal metal conductive layers 15M may be formed by a series of processes of forming a conductive material to gap-fill the recesses 15R and etching the conductive material so that the conductive material remains only in the recesses 15R. For example, the horizontal metal conductive layers 15M may be formed of tungsten (W), but the concepts of the present invention are not limited thereto.

Referring to FIG. 6I, preliminary contact layers 23′ may be formed to cover the inner wall of the expanded horizontal recesses 22A and 22B (see FIG. 6H). The preliminary contact layers 23′ may be formed to be separated from each other by the dielectric layer patterns 13″. The preliminary contact layers 23′ may contact both ends of each horizontal metal conductive layer 15M. For example, the preliminary contact layers 23′ may be made of or include polysilicon that is doped with an N-type impurity.

Subsequently, the third sacrificial layer 24 may be formed to fill the expanded horizontal recesses 22A and 22B (see FIG. 6H) over the preliminary contact layer 23′. The third sacrificial layer 24 may include a material having an etch selectivity with respect to the dielectric layer patterns 13″ and the preliminary contact layer 23′. The third sacrificial layer 24 may include, for example, silicon nitride.

Referring to FIG. 6J, the preliminary contact layer 23′ interposed between the dielectric layer patterns 13″ and the third sacrificial layer 24 may be etched. As the preliminary contact layer 23′ interposed between the dielectric layer patterns 13″ and the third sacrificial layer 24 is etched, the first and second contact nodes 23 and 30 respectively contacting both ends of each of the horizontal metal conductive layers 15M may be formed. The first and second contact nodes 23 and 30 may be separated from each other by the dielectric layer patterns 13″.

Referring to FIG. 6K, the third sacrificial layer 24 (see FIG. 6J) may be removed. By removing the third sacrificial layer 24 (see FIG. 6J), the first and second contact nodes 23 and 30 respectively in contact with both ends of each of the horizontal metal conductive layers 15M may be exposed.

Referring to FIG. 6L, the electrode portion 31N of the vertical conductive line and the storage node 31 of the reservoir capacitor may be formed over the first and second contact nodes 23 and 30. The electrode portion 31N of the vertical conductive line and the storage node 31 of the reservoir capacitor may conformally cover the expanded horizontal recesses 22A and 22B (see FIG. 6K).

The electrode portion 31N of the vertical conductive line may be coupled to the horizontal metal conductive layer 15M through the first contact node 23. The storage node 31 of the reservoir capacitor may be coupled to the horizontal metal conductive layer 15M through the second contact node 30.

The electrode portion 31N of the vertical conductive line and the storage node 31 of the reservoir capacitor may be formed in a symmetrical structure. The electrode portion 31N of the vertical conductive line and the storage node 31 of the reservoir capacitor that are facing each other may have a bilaterally symmetrical structure.

Referring to FIG. 6M, the dielectric layer patterns 13″ (see FIG. 6I) may be horizontally recessed through the first and second openings 18 and 19. The separation portion 13 may be formed by partially etching the dielectric layer patterns 13″ (see FIG. 6L).

At the same time, the electrode portion 31N of the vertical conductive line and the storage node 31 of the reservoir capacitor may have the outer wall exposed to have a cylindrical shape. The electrode portion 31N of the vertical conductive line and the storage node 31 of the reservoir capacitor that are facing each other may have a bilaterally symmetrical cylindrical shape.

Referring to FIG. 6N, a fourth sacrificial layer 25 and a dielectric layer 31 may be formed to cover the entire surface including the electrode portion 31N of the vertical conductive line and the storage node 31 of the reservoir capacitor.

Referring to FIG. 6O, a mask pattern 26 that opens the first opening 18 may be formed over the hard mask layer 17.

Subsequently, the fourth sacrificial layer 25 in the first opening 18 may be removed. As a result, the electrode portion 31N of the vertical conductive line having a cylindrical shape may be exposed in the first opening 18.

Referring to FIG. 6P, the mask pattern 26 (see FIG. 6O) may be removed. When the mask pattern 26 is formed of a photoresist, the mask pattern 26 may be removed through an oxygen stripping process.

Referring to FIG. 6Q, the pillar portion 27P and the extension portion 27E of the vertical conductive line filling the first opening 18 over the electrode portion 31N of the vertical conductive line and the plate node 33 filling the second opening 19 over the storage node 31 of the reservoir capacitor may be formed.

Accordingly, the vertical conductive line in which the electrode portion 31N, the extension portion 27E, and the pillar portion 27P are stacked may be formed in the first opening 18 (see FIG. 6P), and the reservoir capacitor RCAP in which the storage node 31, the dielectric layer 32, and the plate node 33 are stacked may be formed in the second opening 19 (see FIG. 6P).

According to an embodiment of the present invention, it is possible to form a reservoir capacitor of an MIM structure applying the same reticle as that of the memory cell array, thereby preventing a decrease in the process margins that may be caused due to the formation of an additional reticle.

According to an embodiment of the present invention, a three-dimensional array of reservoir capacitors may be formed horizontally from the memory cell array in the same structure as that of the cell capacitors of the three-dimensional memory cell array, thereby securing the area of the reservoir capacitors and increasing the capacitance of the reservoir capacitors.

According to an embodiment of the present invention, the resistance of the vertical conductive line may be reduced by increasing the volume of the vertical conductive line.

While the present invention has been described with respect to specific embodiments, it will be apparent to those skilled in the art that various changes and modifications may be made without departing from the spirit and scope of the invention as defined in the following claims. Furthermore, the embodiments may be combined to form additional embodiments.

What is claimed is:

1. A semiconductor device, comprising:
a lower structure;
a plurality of horizontal conductive layers oriented in a direction parallel to a surface of the lower structure;
a plurality of reservoir capacitors commonly coupled to first-side ends of the horizontal conductive layers, wherein each of the plurality of the reservoir capacitors is vertically stacked over the lower structure, and includes a cylindrical storage node; and
a vertical conductive line commonly coupled to second-side ends opposite to first-side ends of the horizontal conductive layers, extending in a direction perpendicular or substantially perpendicular to the surface of the lower structure, and including a plurality of electrode portions, each electrode portion being symmetrical with the cylindrical storage node of a corresponding reservoir capacitor.

2. The semiconductor device of claim 1, wherein each of the reservoir capacitors includes:
cylindrical storage nodes respectively coupled to the first-side ends of the horizontal conductive layers;
a dielectric layer covering the storage nodes; and
a plate node over the dielectric layer.

3. The semiconductor device of claim 2, wherein the plate node is oriented vertically in the direction perpendicular or substantially perpendicular to the surface of the lower structure.

4. The semiconductor device of claim 1, wherein the horizontal conductive layers include a semiconductor material, a doped semiconductor material, an oxide semiconductor material, or a metal-based material.

5. The semiconductor device of claim 1, wherein the horizontal conductive layers include a doped silicon material that is doped with an N-type impurity.

6. The semiconductor device of claim 1, wherein the horizontal conductive layers include a metal material.

7. The semiconductor device of claim 1, wherein the horizontal conductive layers include tungsten.

8. The semiconductor device of claim 1, further comprising:
first contact nodes disposed between the horizontal conductive layers and the electrode portions of the vertical conductive line; and
second contact nodes disposed between the horizontal conductive layers and the reservoir capacitors.

9. The semiconductor device of claim 8, wherein the first contact nodes and the second contact nodes include polysilicon doped with an N-type impurity.

10. The semiconductor device of claim 1, wherein the vertical conductive line includes
a pillar portion oriented perpendicularly in a direction perpendicular or substantially perpendicular to the surface of the lower structure;
extension portions extending horizontally from the pillar portion; and
cylindrical electrode portions covering at least a portion of each of the extension portions.

11. The semiconductor device of claim 10, wherein the cylindrical electrode portions are arranged to be bilaterally symmetrical based on the pillar portion.

12. The semiconductor device of claim 1, wherein the lower structure includes a control circuit for controlling the reservoir capacitors.

13. The semiconductor device of claim 1, further comprising:
a memory cell array disposed over the lower structure and disposed horizontally from the reservoir capacitors.
